(19) United States
(12) Patent Application Publication
(10) Pub. No.: US 2012/0199904 A1
(43) Pub. Date: Aug. 9, 2012

(54) SEMICONDUCTOR DEVICE AND METHOD FOR MANUFACTURING THE SAME

(75) Inventor: Kenji SASAKI, Kanagawa (JP)

(73) Assignee: RENESAS ELECTRONICS CORPORATION, Kanagawa (JP)

(21) Appl. No.: 13/359,098

(22) Filed: Jan. 26, 2012

(30) Foreign Application Priority Data
Feb. 3, 2011 (JP) 2011-021410

(51) Int. Cl. H01L 29/78; H01L 21/336

(52) U.S. Cl. 257/343; 438/286; 257/E29.256; 257/E21.417

(57) ABSTRACT

A field drain insulating part has a first insulating film and a high dielectric constant insulating film. The first insulating film is positioned at least in the center of the field drain insulating part in a plan view. The high dielectric constant insulating film is positioned at a part close to a drain region in the edge of the bottom surface of the field drain insulating part, and has a higher dielectric constant than the first insulating film. The high dielectric constant insulating film is not positioned in the center of the field drain insulating part in a plan view.

### CROSS-REFERENCE TO RELATED APPLICATIONS

The disclosure of Japanese Patent Application No. 2011-21410 filed on Feb. 3, 2011 including the specification and abstract is incorporated herein by reference in its entirety.

### BACKGROUND

The present invention relates to a semiconductor device having an LDMOS transistor and a method for manufacturing the same.

An LDMOS transistor has been known as one of high voltage transistors. In the LDMOS transistor, a field drain insulating part is formed in a substrate in a region between a gate electrode and a drain diffusion region. The field drain insulating part is provided in order to improve breakdown voltage between the drain and the substrate (BVds). According to a technology described in Patent Document 1, the field drain insulating part is formed by the same process as a process for element separation film having a structure of STI (Shallow Trench Isolation). According to technologies described in Patent Document 2 and Patent Document 3, the field drain insulating part has an LOCOS structure. Particularly, in Patent Document 3, the element separation film also has the LOCOS structure.

### [Patent Document 1]

Japanese Patent Application Publication (Translation of PCT Application) No. 2008-535235

### [Patent Document 2]

Japanese Patent Application Publication No. 2006-324346

### [Patent Document 3]

Japanese Patent Application Publication No. 2009-059949

### SUMMARY

On-breakdown voltage is required for the LDMOS transistor. The inventors of the present invention have investigated so that the on-breakdown voltage can be improved.

According to an aspect of the present invention, a semiconductor device includes:

a semiconductor substrate;

a first conductive type of a first conductive type well formed in the semiconductor substrate;

a second conductive type of a second conductive type well formed in the semiconductor substrate and formed adjacent to the first conductive type well;

a gate insulating film arranged over the semiconductor substrate across a part of the first conductive type well and a part of the second conductive type well;

a gate electrode located over the gate insulating film,

the second conductive type of a second impurity region formed over a surface layer of the first conductive type well; and

the second conductive type of a first impurity region formed over a surface layer of the second conductive type well and formed apart from the gate electrode in a plan view; and

a field drain insulating part in which at least a part of the field drain insulating part is formed under the gate insulating film and which is formed over a surface of the second conductive type well between under the gate insulating film and the first impurity region,

in which the field drain insulating part includes:

a first insulating film positioned at least in a center part of the field drain insulating part in a plan view; and

a high dielectric constant insulating film arranged at least at a region close to the first impurity region in an edge of a bottom surface of the field drain insulating part and having a higher dielectric constant than the first insulating film is provided.

When the first impurity region is used as the drain, electric field is concentrated in a region positioned close to the first impurity region in the field drain insulating part. In this case, impact ionization is generated in the region positioned close to the first impurity region, and thereby the on-breakdown voltage becomes lower. On the contrary in the present invention, a high dielectric constant insulating film having higher dielectric constant than the first insulating film is arranged at least a part close to the first impurity region at the edge of the bottom surface of the field drain insulating part. Consequently, the concentration of the electric field in the region positioned close to the first impurity region in the field drain insulating part can be suppressed. Therefore, the on-breakdown voltage is improved.

According to another aspect of the present invention, a method for manufacturing a semiconductor device includes the steps of:

forming a groove in a semiconductor substrate;

forming a field drain insulating part by embedding an insulating film into the groove;

forming a gate insulating film and a gate electrode over the semiconductor substrate; and

forming a first impurity region and a second impurity region in a position facing each other through the gate electrode in a plan view,

in which the semiconductor substrate has a first conductive type of a first conductive type well and a second conductive type of a second conductive type well adjacent to the first conductive type well, and

in which the gate insulating film is arranged over the semiconductor substrate across a part of the first conductive type well and a part of the second conductive type well, and

in which the second impurity region is the second conductive type and is formed over a surface layer of the first conductive type well, and

in which the first impurity region is the second conductive type and is formed over a surface layer of the second conductive type well and is formed apart from the gate electrode in a plan view, and

in which at least a part of the field drain insulating part is formed under the gate insulating film and the field drain insulating part is formed over the surface layer of the second conductive type well between under the gate insulating film and the first impurity region, and

in which the step of forming a field drain insulating part includes the steps of:

forming a high dielectric constant film in the groove;

etching back the high dielectric constant film; and

thereby forming the high dielectric constant film at least in a part facing to the first impurity region at the edge of the bottom surface of the groove is provided.

According to the aspects of the present invention, the on-breakdown voltage of the LDMOS transistor can be improved.

### BRIEF DESCRIPTION OF DRAWINGS

FIG. 1 is a cross-sectional view showing a configuration of a semiconductor device according to the embodiments;

FIG. 2 is a cross-sectional view taken from the line B-B′ of FIG. 1;

FIGS. 3A and 3B are cross-sectional views showing a method for manufacturing the semiconductor device shown in FIG. 1 and FIG. 2;

FIGS. 4A and 4B are cross-sectional views showing a method for manufacturing the semiconductor device shown in FIG. 1 and FIG. 2;

FIGS. 5A and 5B are cross-sectional views showing a method for manufacturing the semiconductor device shown in FIG. 1 and FIG. 2;

FIG. 6 is a plain view showing a first modification of the semiconductor device shown in FIG. 1 and FIG. 2;

FIG. 7 is a plain view of the semiconductor device shown in FIG. 6.

FIG. 8 is a plain view showing a second modification of the semiconductor device shown in FIG. 1 and FIG. 2;

FIG. 9 is a schematic view for illustrating a reason why the on-breakdown voltage is decreased in the LDMOS transistor;

FIG. 10 is a cross-sectional view showing a configuration of a semiconductor device according to the reference embodiment;

FIGS. 11A, 11B and 11C are views showing a simulation result of electric field distribution at the time of applying on-voltage to a gate electrode in the LDMOS transistor;

FIG. 12 is a graph showing a drain current-drain voltage property (an Id-Vd property) when the LDMOS transistor has the structure shown in FIG. 7, FIG. 8 and FIG. 10, respectively;

FIG. 13 is a schematic view for illustrating a reason why the off-breakdown voltage is decreased in the LDMOS transistor;

FIG. 14 is a graph showing strength of on-breakdown voltage and off-breakdown voltage BVds in the structure shown in FIG. 7 and FIG. 8 when the structure shown in FIG. 10 is used as the standard; and

FIG. 15 is a view showing how a ratio X of a width w₁ of the high dielectric constant insulating film (refer to FIG. 1) to a width w₂ of the field drain insulating part (refer to FIG. 1) has an effect on the on-breakdown voltage and the off-breakdown voltage BVds.

### DETAILED DESCRIPTION

Hereinafter, preferred embodiments of the present invention are described using drawings. Here, the same reference numeral is assigned to a similar configuration element, and description for the element is arbitrarily omitted in all drawings.

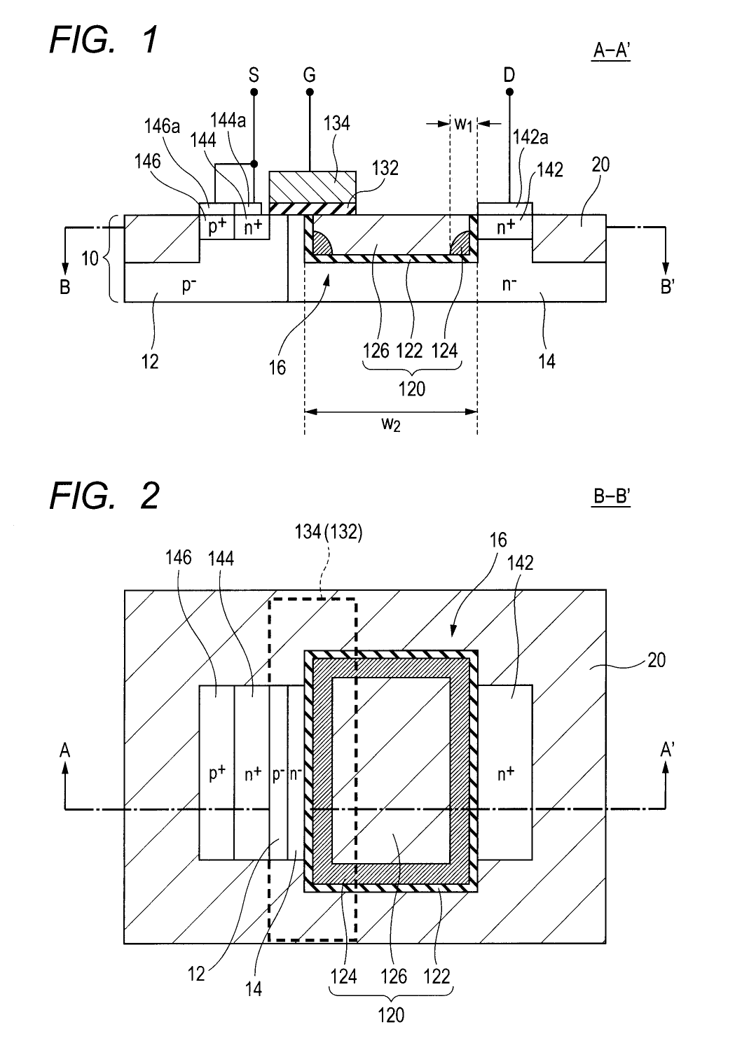

FIG. 1 is a cross-sectional view showing a configuration of a semiconductor device according to the embodiments. This semiconductor device has an LDMOS (Laterally Diffused Metal Oxide Semiconductor) transistor. Specifically, this semiconductor device has a semiconductor substrate 10, a gate insulating film 132, a gate electrode 134, a first impurity region (a drain region: for example, an n-type impurity region) 142, a second impurity region (a source region: for example, an n-type impurity region) 144 and a field drain insulating part 120. The semiconductor substrate 10 is, for example, a silicon substrate. The gate insulating film 132 is formed over the semiconductor substrate 10. The gate electrode 134 is formed over the gate insulating film 132. The gate insulating film 132 is, for example a silicon dioxide film and the gate electrode 134 is a polysilicon film. The drain region 142 and the source region 144 face each other through the gate electrode 134 in a plan view. In particular, the drain region 142 is apart from the gate electrode 134 in a plan view. The field drain insulating part 120 is formed in the semiconductor substrate 10. The field drain insulating part 120 is positioned between the gate electrode 134 and the drain region 142 in a plan view. In particular, at least a part of the field drain insulating part 120 is positioned under the gate insulating film 132, and positioned in a region from under the gate insulating film 132 to the drain region 142 in a surface layer of a second conductive type well 14.

The field drain insulating part 120 has a first insulating film 126 and the high dielectric constant insulating film 124. The first insulating film 126 is positioned at least in a center part of the field drain insulating part 120 in a plan view. The high dielectric constant insulating film 124 is positioned at least at a part positioned in the drain region 142 side in the edge of the bottom surface of the field drain insulating part 142, and has a higher dielectric constant than the first insulating film 126. In this embodiment, the high dielectric constant insulating film 124 is not positioned in the center part of the field drain insulating part 120 in a plan view. Hereinafter, the semiconductor device is described in detail.

In this embodiment, the LDMOS transistor is formed in an element forming region. This element forming region is separated from other regions by the element separation film 20. The element separation film 20 is, for example, a silicon dioxide film, and embedded into a groove formed in the semiconductor substrate 10. The element separation film 20 does not have the high dielectric constant insulating film 124. In other words, the element separation film 20 has a different structure from the field drain insulating part 120.

Space is located between the source region 144 and the field drain insulating part 120 in a plan view. The gate insulating film 132 and the gate electrode 134 are formed over the space and over a region facing to the source region 144 in the field drain insulating part 120. Consequently, a region positioned between the source region 144 and the field drain insulating part 120 in the semiconductor substrate 10 is a channel region of the LDMOS transistor. The gate insulating film 132 and the gate electrode 134 do not positioned over the drain region 142 and over the source region 144.

In the semiconductor substrate 10 positioned in the element forming region, a first conductive type well 12 (for example a p type well) and a second conductive type well 14 (for example an n type well) are adjacently located each other. The source region 144 is located in the surface layer of the first conductive type well 12 and the drain region 142 is located in the surface layer of the second conductive type well 14. A silicide layer (not illustrated), for example, is formed over each surface layer of the drain region 142, the source region 144 and a substrate contact part 146. Electrodes 142a, 144a and 146 made of metal or the like are formed over the drain region 142, the source region 144 and the substrate contact part 146, respectively. An interface between the first conductive type well 12 and the second conductive type well 14 is overlapped with the channel region of the LDMOS transistor. In other words, the gate insulating film 132 is arranged over the semiconductor substrate 10 across a part of the first conductive type well 12 and a part of the second conductive type well 14.

In the first conductive type well 12, a first conductive type of a substrate contact part 146 is located. The substrate contact part 146 is a high concentration impurity region compared with the first conductive type well 12, and is located in the opposite side of the field drain insulating part 120 through the source region 144. In this embodiment, the substrate contact part 146 is adjacent to the source region 144, and has the same electric potential as the source region 144.

The field drain insulating part 120 contacts to the drain region 142, and is embedded in the groove 16 formed in the semiconductor substrate 10. A width w2 of the field drain insulating part 120 in a direction intersecting at right angles to an orientation direction of the gate electrode 134 is wider than the width of the drain region 142 and the source region 144. A silicon dioxide film 122 is formed over the bottom surface and the side surfaces of the groove 16. The silicon dioxide film 122 is, for example, a thermal oxidation film. The high dielectric constant insulating film 124 is formed at the edge of the bottom surface of the groove 16. The high dielectric constant insulating film 124 is formed from at least one of a silicon nitride (SiN) film, a hafnium oxide (HfO₂) film, tantalum oxide, titanium oxide, yttrium oxide, niobium pentoxide and zirconium oxide. The first insulating film 126 is embedded in a space where the high dielectric constant insulating film 124 is not positioned inside the groove 16. The first insulating film 126 is, for example, a silicon dioxide (SiO₂) film.

The high dielectric constant insulating film 124 has a side-wall shape. In this embodiment, the high dielectric constant insulating film 124 is formed along the edge around the entire circumference of the bottom surface of the groove 16. In other words, the high dielectric constant insulating film 124 is also formed at a part positioned under the gate electrode (a part positioned in the source region 144 side) in the edge of the bottom surface of the groove 16. The width w₁ of the high dielectric constant insulating film 124 (including a width of the silicon dioxide film 122) is 10% or more and 40% or less of the width w₂ of the field drain insulating part 120 in the direction intersecting at right angles to the orientation direction of the gate electrode 134.

In the example shown in FIG. 1, a depth of the element separation film 20 and a depth of the field drain insulating part 120 are equal to one another. However, the field drain insulating part 120 may be shallower or may be deeper than the element separation film 20.

FIG. 2 is a cross-sectional view taken from the line B-B′ of FIG. 1. FIG. 1 corresponds to a cross-sectional view taken from the line A-A′ of FIG. 2. For the purpose of description, the gate insulating film 132 and the gate electrode 134 are shown in a dashed line in FIG. 2.

In the example shown in this view, a planar shape of the field drain insulating part 120 is polygon and more particularly rectangle. As described above, the high dielectric constant insulating film 124 is formed at least one side close to the drain region 142 in the bottom surface of the field drain insulating part 120 in a plan view. Preferably, the high dielectric constant insulating film 124 is also formed in one side close to the source region 144 in the bottom surface of the field drain insulating part 120 in a plan view. In this embodiment, the high dielectric constant insulating film 124 is formed along the edge around the entire circumference of the bottom surface of the groove 16. When the high dielectric constant insulating film 124 is seen from the orientation direction (an up and down direction in the view) of the gate electrode 134, the drain region 142, the source region 144 and the substrate contact part 146 has the same width. This width is narrower than the width of the field drain insulating part 120.

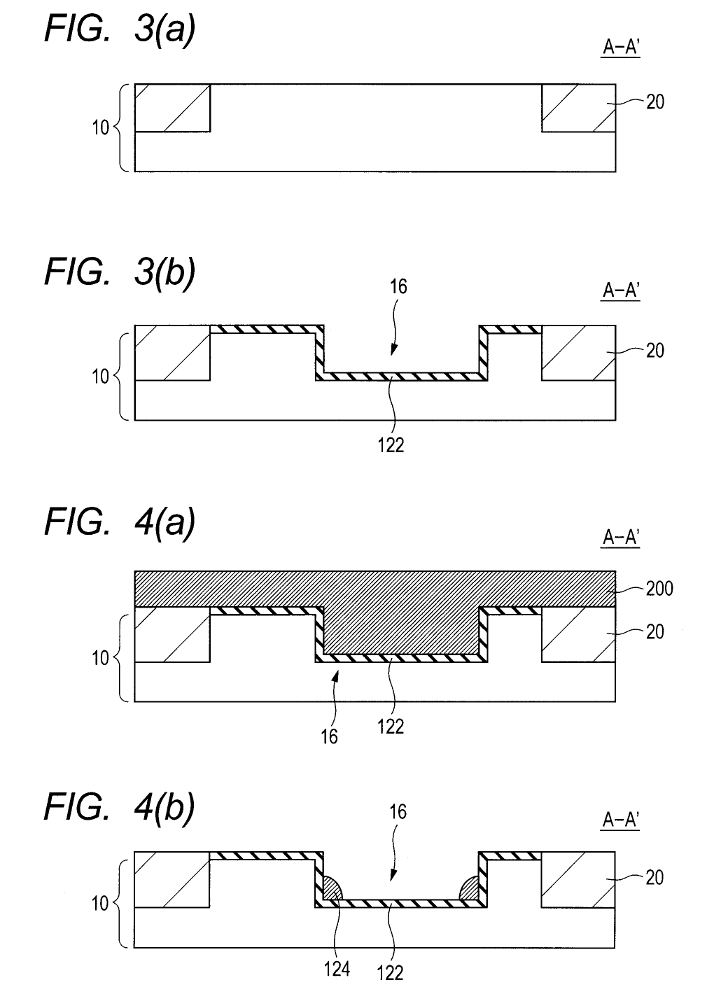

FIGS. 3A, 3B, 4A, 4B, 5A and 5B are cross-sectional views showing a method for manufacturing the semiconductor device shown in FIG. 1 and FIG. 2. This method for manufacturing the semiconductor device has the following steps. First, the groove 16 is formed in the semiconductor substrate 10. Subsequently, the field drain insulating part 120 is formed by embedding an insulating film into the groove 16. Subsequently, the gate insulating film 132 and the gate electrode 134 are formed over the semiconductor substrate 10. Subsequently, the drain region 142 and the source region 144 are formed. The step for forming the field drain insulating part 120 has the following steps. First, a high dielectric constant film 200 is formed in the groove 16, and then the high dielectric constant insulating film 124 is formed by etching back the high dielectric constant film 200. Then, the first insulating film 126 is embedded into a remaining part of the groove 16. Hereinafter, the method for manufacturing the semiconductor is described in detail.

First, a groove is formed in the semiconductor substrate 10 and an insulating film is embedded into the groove, as shown in FIG. 3A. Thereby, the element separation film 20 is formed.

Subsequently, a mask film (not illustrated) is formed over the semiconductor substrate 10 and the semiconductor substrate is etched using the mask film as a mask, as shown in FIG. 3B. Thereby, the groove 16 is formed in the semiconductor substrate 10. Subsequently, the semiconductor substrate 10 is oxidized by heating. Thereby, the silicon dioxide film 122 is formed over the bottom surface and the side surfaces of the groove 16. Here, the silicon dioxide film 122 is also formed in a region where the element separation film 20 is not formed over the surface of the semiconductor substrate 10.

The silicon dioxide film may be formed by a CVD method. In this case, the silicon dioxide film 122 is also formed over the element separation film 20.

Subsequently, the high dielectric constant film 200 is formed in the groove 16, over the semiconductor substrate and over the element separation film 20, as shown in FIG. 4A. The high dielectric constant film 200 is formed by, for example, a plasma CVD method.

Subsequently, the high dielectric constant film 200 is etched back, as shown in FIG. 4B. Thereby, the high dielectric constant insulating film 124 is formed along the edge around the entire circumference of the bottom surface of the groove 16.

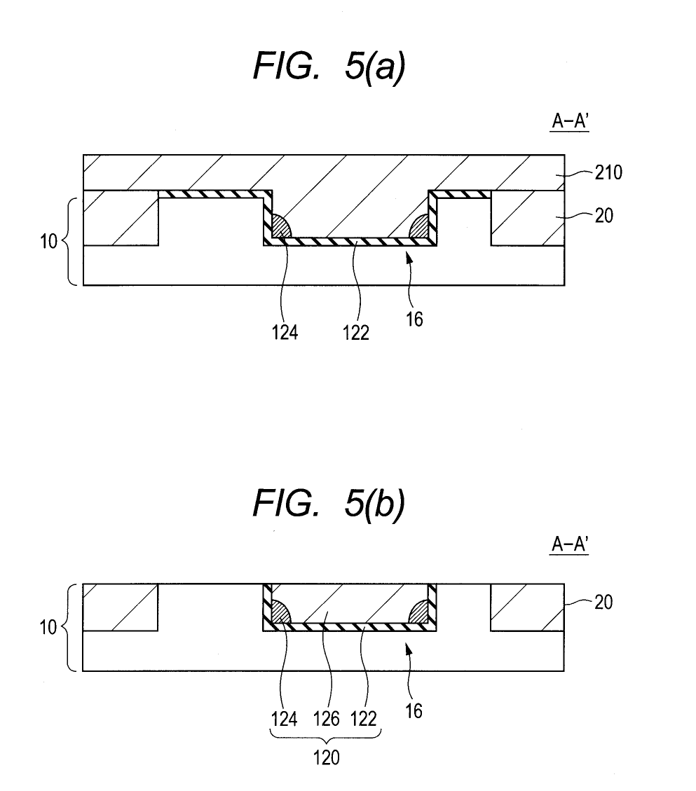

Subsequently, an insulating film 210 is formed in the groove 16, over the semiconductor substrate and over the element separation film 20, as shown in FIG. 5A. The insulating film 210 is formed by, for example, the plasma CVD method.

Subsequently, a part in the insulating film 210 which is positioned over the element separation film 20 and over the semiconductor substrate 10 is removed by a CPM method. Thereby, the first insulating film 126 is formed. As described above, the field drain insulating part 120 is formed.

Thereafter, the first conductive type well 12 and the second conductive type well 14 is formed in the semiconductor substrate 10. Subsequently, the gate insulating film 132 and the gate electrode 134 are formed. Subsequently, the substrate contact part 146 is formed by selectively injecting the first conductive type impurity into the semiconductor substrate 10. The drain region 142 and the source region 144 are formed by selectively injecting the second conductive type impurity into the semiconductor substrate 10. Thereafter, electrodes 142a, 144a and 146a are formed. As described above, the semiconductor device shown in FIG. 1 and FIG. 2 is formed.

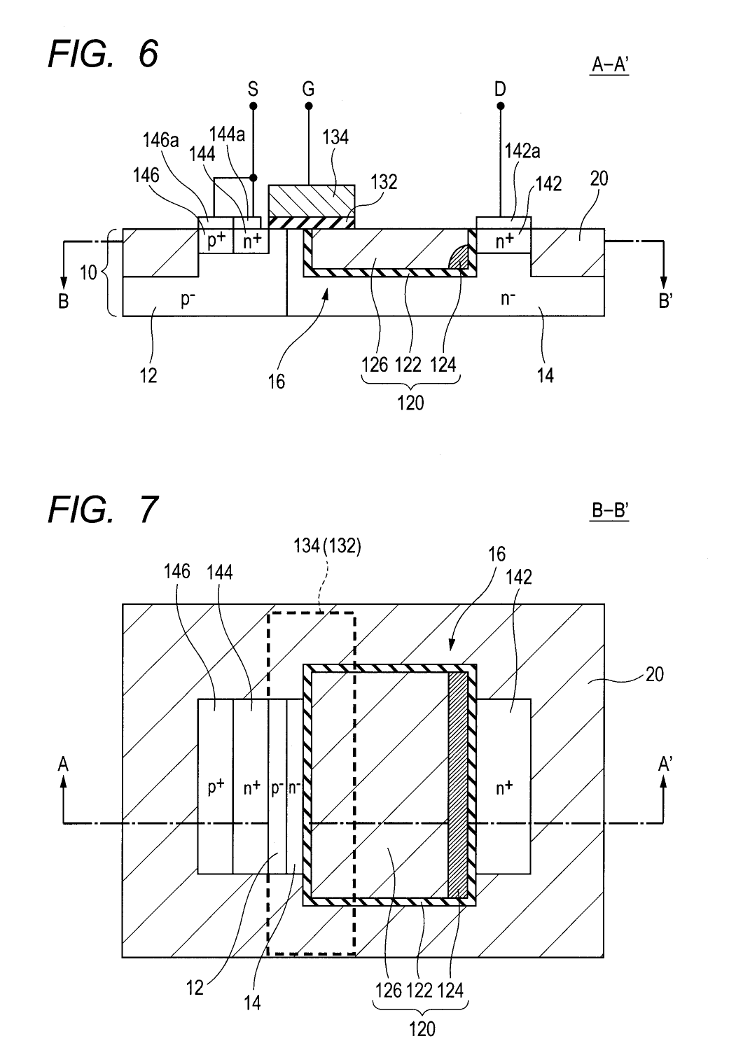

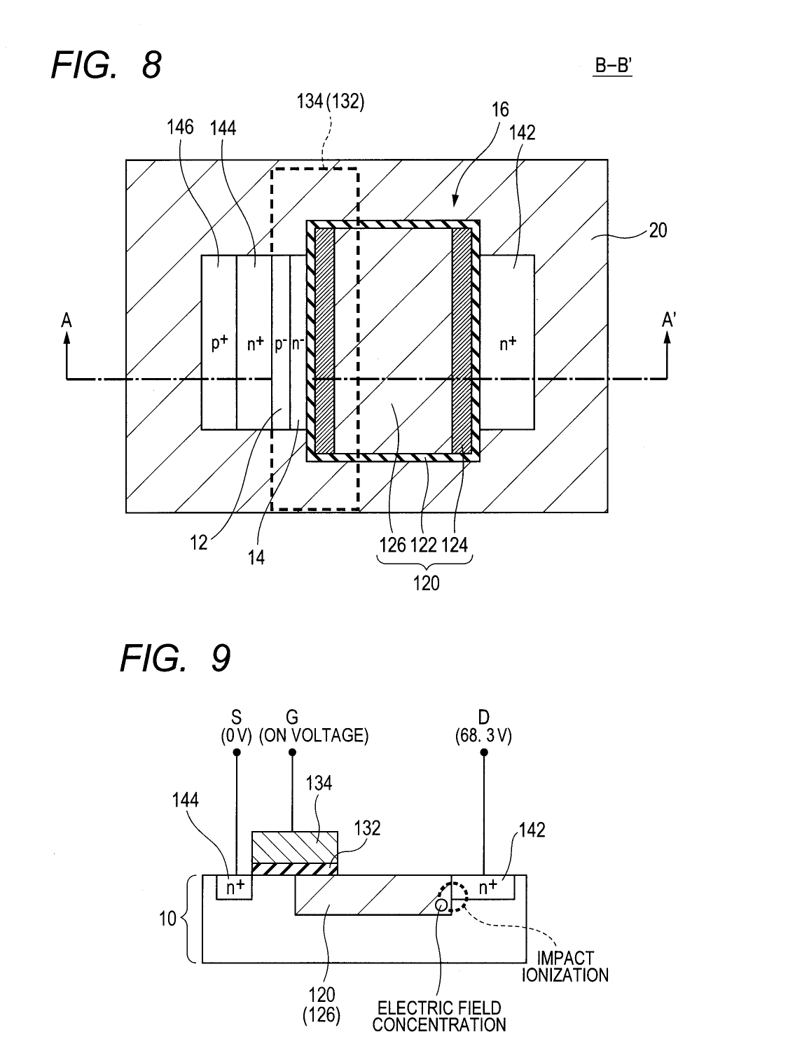

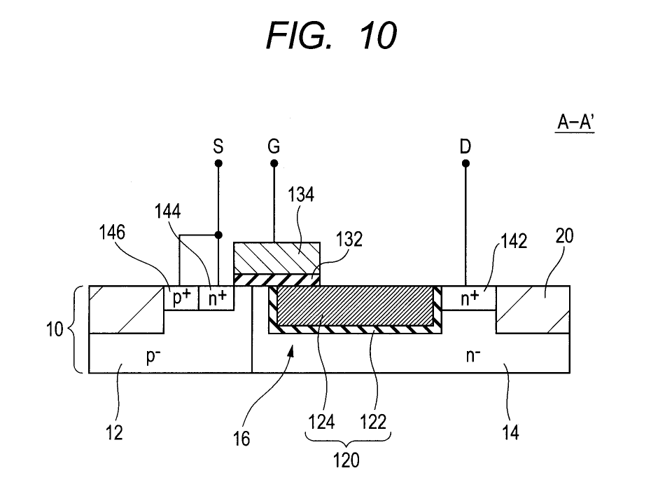

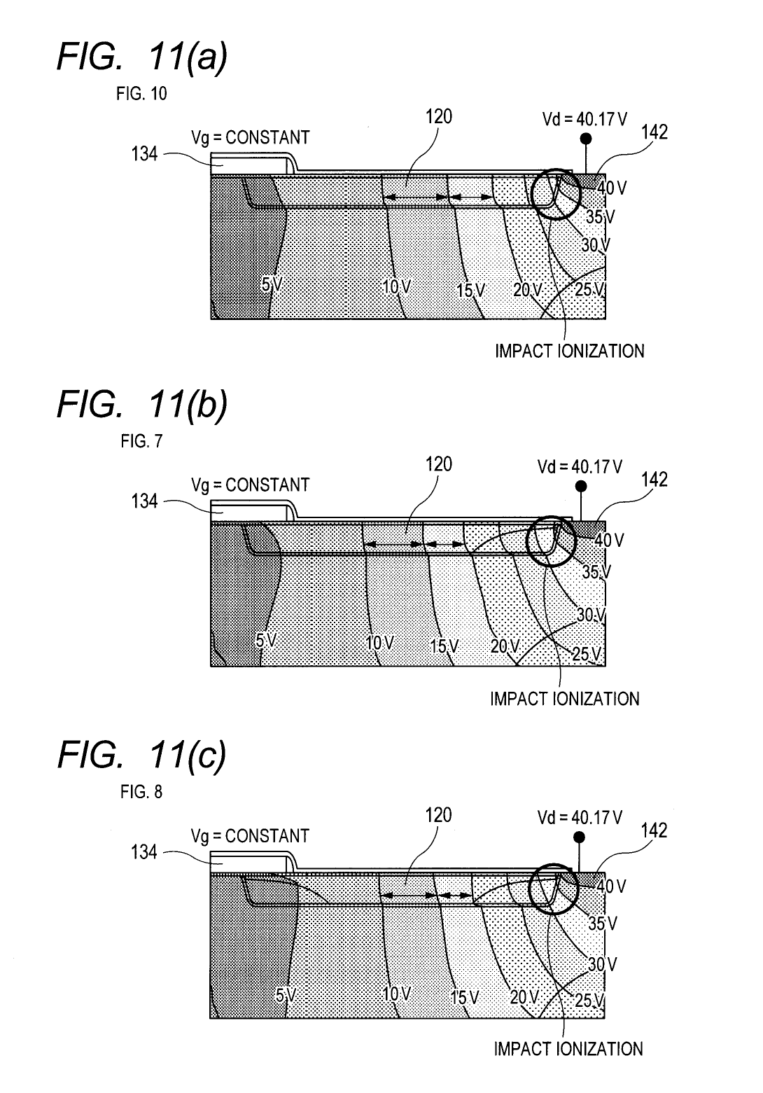

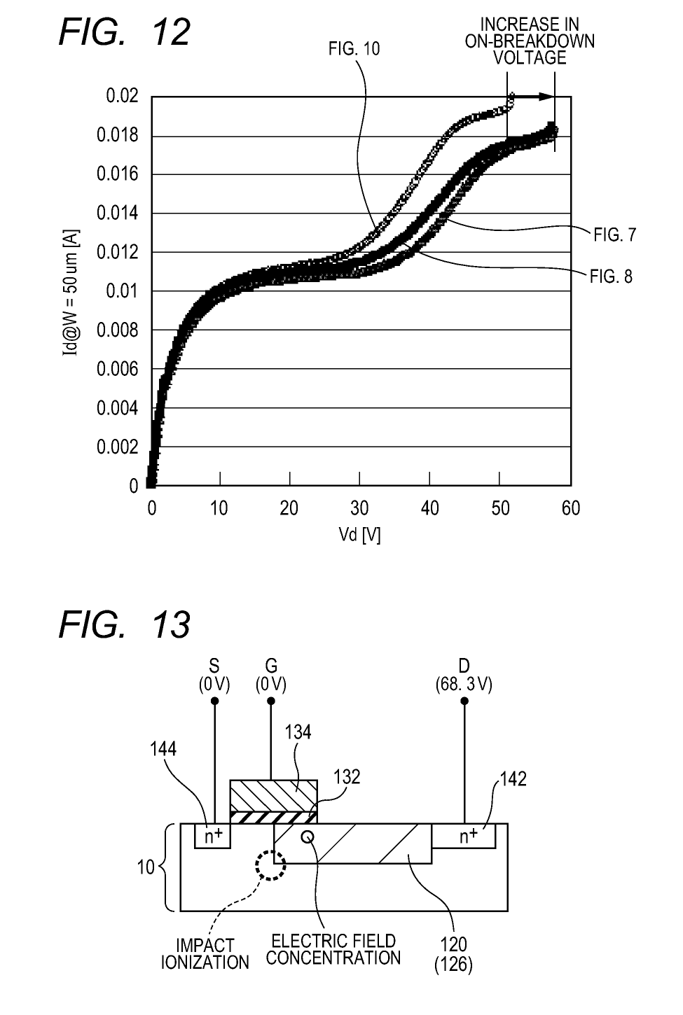

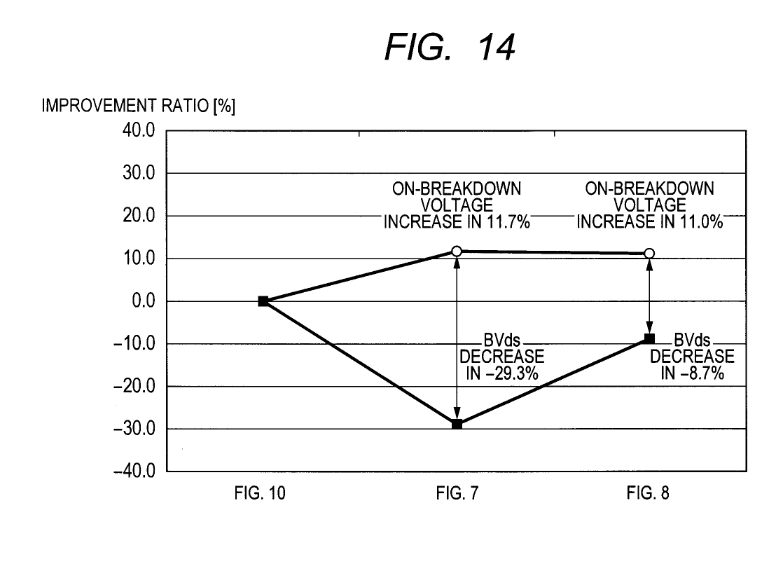

FIG. 6 is a cross-sectional view showing a first modification of the semiconductor device shown in FIG. 1 and FIG. 2. FIG. 7 is a plain view of the semiconductor device shown in FIG. 6. FIG. 6 corresponds to a cross-sectional view taken from the line A-A′ of FIG. 7. The semiconductor device shown in FIG. 6 has a similar configuration to the semiconductor device shown in FIGS. 1 and 2 except that the high dielectric constant insulating film 124 is formed only at the facing side to the drain region 142 in the edge of the bottom surface of the groove 16.

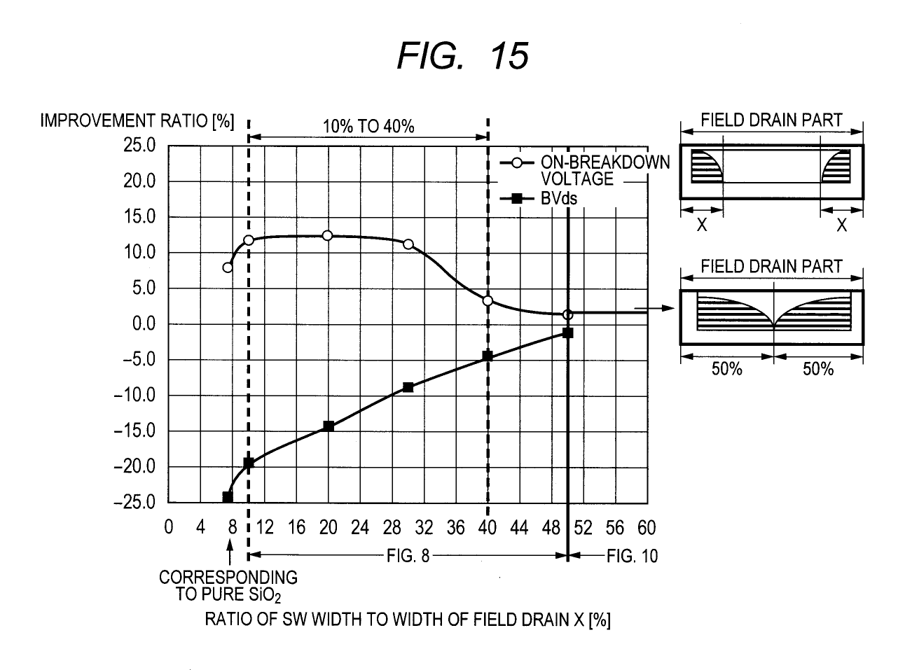

FIG. 8 is a plain view showing a second modification of the semiconductor device shown in FIG. 1 and FIG. 2. The cross-sectional view taken from the line A-A′ of FIG. 8 is similar to FIG. 1. The semiconductor device shown in FIG. 8 has a similar configuration to the semiconductor device shown in FIG. 1 and FIG. 2 except that the high dielectric constant insulating film 124 is formed only at the facing side to the drain region 142 and at a side positioned under the gate electrode 134 in the edge of the bottom surface of the groove 16.

The semiconductor devices shown in FIG. 6 to FIG. 8 are formed by, for example, removing the high dielectric constant insulating film 124 by etching after covering with a resist film a part of the high dielectric constant insulating film 124 which is desired to remain, after the step shown in FIG. 4 and before the step shown in FIG. 5.

Subsequently, operation and effect of this embodiment is described. First, a case that the field drain insulating part 120 is formed by a single material (for example, the first insulating film 126) except the silicon dioxide film 122 (not illustrated in the view) is considered using FIG. 9. When the field drain insulating part 120 has the structure, it is assumed that on-voltage is applied to the gate electrode 134, and source voltage Vs=0 V is applied to the source region 144, and predetermined magnitude of drain voltage is applied to the drain region 142 (in other words, the transistor is in an on state). In this case, gradient of electric potential becomes large in the part positioned close to the drain region 142 in the field drain insulating part 120.

When an intense electric field region where the gradient of electric potential is large in the field drain insulating part 120 exists, impact ionization is easy to be generated in a part positioned close to the intense electric field region in the semiconductor substrate 10. The impact ionization is a phenomenon in which many electron-hole pairs are generated by collision of electrons accelerated by electric field and a crystal lattice. In the example shown in FIG. 9, the impact ionization is generated in the part positioned close to the drain region 142. The electron-hole pairs generated in such a location reduce on-breakdown voltage.

Consequently, the inventors of the present invention consider that when the transistor is in an off-state, the impact ionization is suppressed if electric field concentration which is generated in the field drain insulating part 120 can be relaxed, and as a result, on-breakdown voltage of the LDMOS transistor is increased. Therefore, the inventors of the present invention have created each of the structure shown in FIG. 1 and FIG. 2, the structure shown in FIG. 6 and FIG. 7 and the structure shown in FIG. 8.

As shown in FIG. 10 (a reference embodiment), the entire field drain insulating part 120 is also probably formed by the high dielectric constant insulating film 124. However, from the simulation result described below, it has been found that the structure shown in FIG. 10 has an inferior on-breakdown voltage increasing effect to the structure shown in FIG. 1 and FIG. 2, the structure shown in FIG. 6 and FIG. 7 and the structure shown in FIG. 8.

Each view in FIG. 11 shows the simulation result of electric field distribution at the time of applying on-voltage to the gate electrode 134 in the LDMOS transistor. In this simulation, HfO₂ is used as the high dielectric constant insulating film 124 of the field drain insulating part 120 and a silicon dioxide film is used as the first insulating film 126. In addition, 40.17 V is used as drain voltage Vd. Here, 0 V is used as source voltage Vs.

FIG. 11A shows the case that the LDMOS transistor has the structure shown in FIG. 10 (the reference embodiment). FIG. 11B shows the case that the LDMOS transistor has the structure shown in FIG. 7 (the first modification). FIG. 11C shows the case that the LDMOS transistor has the structure shown in FIG. 1 (this embodiment) or FIG. 8 (the second modification). As shown in FIGS. 11, gradient of electric field closed to the drain region 142 is more relaxed in the examples shown in FIG. 11B and FIG. 11C than the example shown in FIG. 11A. This means that on-breakdown voltage in the LDMOS transistor is increased.

FIG. 12 shows a drain current-drain voltage property (an Id-Vd property) when the LDMOS transistors have each structure of FIG. 7, FIG. 8 and FIG. 10. When the drain voltage Vd is increased in a state that constant on-voltage is applied to the gate electrode 134, drain voltage required to be a state in which drain current is rapidly increased is high in the structure shown in FIG. 7 and FIG. 8 compared with the structure shown in FIG. 10. From this result, it is also found that the LDMOS transistor according to this embodiment and modifications has increased on-breakdown voltage compared with the structure shown in FIG. 10.

Off-breakdown voltage BVds is also required for the LDMOS transistor. As shown in FIG. 13, when the field drain insulating part 120 is formed by a single material, it is assumed that gate voltage Vg=0 V is applied to the gate electrode 134, and source voltage Vs=0 V is applied to the source region 144, and predetermined drain voltage is applied to the drain region 142 (in other words, the transistor is in an off state). In this case, electric field tends to be concentrated in the field drain insulating part 120 positioned under the gate electrode 134.

To solve this problem, the structure shown in FIG. 1 and FIG. 2 and the structure shown in FIG. 8 are effective. This is because these structures also have the high dielectric constant insulating film 124 at a region positioned under the gate electrode 134 in the edge of the bottom surface of the field drain insulating part 120.

FIG. 14 shows strength of on-breakdown voltage and off-breakdown voltage BVds in the structures shown in FIG. 7 and FIG. 8 when the structure shown in FIG. 10 is used as the standard. Both structures shown in FIG. 7 and FIG. 8 have increased on-breakdown voltage compared with the structure shown in FIG. 10. On the other hand, the structure shown in FIG. 10 has the highest off-breakdown voltage BVds, while the structure shown in FIG. 8 has high off-breakdown voltage compared with the structure shown in FIG. 7. Form this result, it is found that the structure shown in FIG. 1 and FIG. 2 or the structure shown in FIG. 8 is preferable in order to satisfy both of the on-breakdown voltage and the off-breakdown voltage.

FIG. 15 shows how a ratio X of a width w₁ of the high dielectric constant insulating film (refer to FIG. 1) to a width w₂ of the field drain insulating part (refer to FIG. 1) has an effect on the on-breakdown voltage and the off-breakdown voltage BVds. In the example shown in FIG. 15, X=8% corresponds to absence of the high dielectric constant insulating film 124 (that is, the structure shown in FIG. 9) because the silicon dioxide film 122 is included in the field drain insulating part 120. X=50% corresponds to the structure shown in FIG. 10. From this view, it is found that 10%≦X≦40%, preferably 10%≦X≦30%, and more preferably 20%≦X≦30% are adequate for satisfying both of the on-breakdown voltage and the off-breakdown voltage BVds.

Hereinbefore the embodiment of the present invention is described with reference to the drawings. However, these are exemplifications of the present invention and various configurations can be employed except configurations descried above.

What is claimed is:

1. A semiconductor device comprising:
a semiconductor substrate;
a first conductive type of a first conductive type well formed in the semiconductor substrate;
a second conductive type of a second conductive type well formed in the semiconductor substrate and formed adjacent to the first conductive type well;
a gate insulating film arranged over the semiconductor substrate across a part of the first conductive type well and a part of the second conductive type well;
a gate electrode arranged over the gate insulating film;
the second conductive type of a second impurity region formed over a surface layer of the first conductive type well;
the second conductive type of a first impurity region formed over a surface layer of the second conductive type well and formed apart from the gate electrode in a plan view; and
a field drain insulating part in which at least a part of the field drain insulating part is formed under the gate insulating film and which is formed over a surface of the second conductive type well between under the gate insulating film and the first impurity region,
wherein the field drain insulating part comprises:
a first insulating film positioned at least in a center part of the field drain insulating part in a plan view; and
a high dielectric constant insulating film arranged at least at a region close to the first impurity region in an edge of a bottom surface of the field drain insulating part and having a higher dielectric constant than the first insulating film.

2. The semiconductor device according to claim 1,
wherein the high dielectric constant insulating film is not arranged in the center part of the bottom surface of the field drain insulating part.

3. The semiconductor device according to claim 1,
wherein the first impurity region is a drain region.

4. The semiconductor device according to claim 1,
wherein the high dielectric constant insulating film is also formed at the second impurity region side in the edge of the bottom surface of the field drain insulating part.

5. The semiconductor device according to claim 4,
wherein the high dielectric constant insulating film is formed along the edge around the entire circumference of the bottom surface of the field drain insulating part.

6. The semiconductor device according to claim 1,
wherein the bottom surface of the field drain insulating part is polygon and,
wherein the high dielectric constant insulating film is formed at one side of the bottom surface close to the first impurity region in a plan view.

7. The semiconductor device according to claim 6,
wherein the high dielectric constant insulating film is also formed at one side of the bottom surface close to the second impurity region in a plan view.

8. The semiconductor device according to claim 1,
wherein a width of the high dielectric constant insulating film is 10% or more and 40% or less of a width of the field drain insulating part in a direction intersecting at right angles to an orientation direction of the gate electrode.

9. The semiconductor device according to claim 1,
wherein the substrate is a silicon substrate, and
wherein the field drain insulating part is embedded in a groove formed in the substrate, and
wherein a silicon dioxide film is formed over a bottom surface and side surfaces of the groove.

10. The semiconductor device according to claim 1,
wherein the first insulating film is a silicon dioxide film, and
wherein the high dielectric constant insulating film is at least one of silicon nitride film, a hafnium oxide film, tantalum oxide, titanium oxide, yttrium oxide, niobium pentoxide and zirconium oxide.

11. The semiconductor device according to claim 1,
wherein the gate insulating film, the gate electrode, the first impurity region, the second impurity region and the field drain insulating part configure a transistor, and
wherein the semiconductor device comprises an element separation film separating the transistor from other regions, and
wherein the element separation film is formed by the first insulating film and does not comprise the high dielectric constant insulating film.

12. A method for manufacturing a semiconductor device, the method comprising the steps of:
forming a groove in a semiconductor substrate;
forming a field drain insulating part by embedding an insulating film into the groove;
forming a gate insulating film and a gate electrode over the semiconductor substrate; and
forming a first impurity region and a second impurity region in a position facing each other through the gate electrode in a plan view,
wherein the semiconductor substrate has a first conductive type of a first conductive type well and a second conductive type of a second conductive type well adjacent to the first conductive type well, and
wherein the gate insulating film is arranged over the semiconductor substrate across a part of the first conductive type well and a part of the second conductive type well, and
wherein the second impurity region is the second conductive type and is formed over a surface layer of the first conductive type well, and
wherein the first impurity region is the second conductive type and is formed over a surface layer of the second conductive type well and is formed apart from the gate electrode in a plan view, and
wherein at least a part of the field drain insulating part is formed under the gate insulating film and the field drain insulating part is formed over the surface layer of the second conductive type well between under the gate insulating film and the first impurity region, and
wherein the step of forming a field drain insulating part includes the steps of:
forming a high dielectric constant film in the groove;
etching back the high dielectric constant film, and
thereby forming the high dielectric constant film at least at a part facing to the first impurity region in the edge of the bottom surface of the groove.

13. The method for manufacturing the semiconductor device according to claim 12, further comprising:
a step of embedding a first insulating film having a lower dielectric constant than the dielectric constant film into a remaining part of the groove, after the step of forming the high dielectric constant film,

14. The method for manufacturing the semiconductor device according to claim 12, the substrate being a silicon substrate, the method further comprising:
a step of forming a silicon dioxide film over the bottom surface and the side surfaces of the groove between the steps of forming the groove and forming the field drain insulating part.

15. The method for manufacturing the semiconductor device according to claim 12,
wherein the gate insulating film, the gate electrode, the first impurity region, the second impurity region and the field drain insulating part configure a transistor, and
wherein the method comprises a step of embedding an element separation film separating the transistor from other regions, before the step of forming the groove.
